(19) United States
(12) Patent Application Publication
(10) Pub. No.: US 2005/0099214 A1
(43) Pub. Date: May 12, 2005

(54) Charge pump capable of responding to high frequency

(75) Inventor: Kiyoshi Sasai, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 10/979,015

(22) Filed: Nov. 1, 2004

(30) Foreign Application Priority Data
Nov. 6, 2003 (JP) 2003-376734

(51) Int. Cl. H03L 7/06

(52) U.S. Cl. 327/157

(57) ABSTRACT

A charge pump capable of responding to a high frequency contains a first constant current source 1 connected between a power supply Vcc and an output terminal Out; and first and second NPN transistors 2 and 3 between the output terminal Out and a ground with their collectors connected to the output terminal Out. A first signal output from a phase comparator is input to a base of the first NPN transistor 2, and a second signal output from the phase comparator is input to a base of the second NPN transistor 3.

### BACKGROUND OF THE INVENTION

1. Field of the Invention

The present invention relates to a charge pump for a PLL circuit, which is capable of performing a push-pull operation.

2. Description of the Related Art

A conventional charge pump will be described with reference to FIG. 2. In the charge pump, an input terminal 23a is connected to one output terminal of a phase comparator (not shown) while an input terminal 23b is connected to the other output terminal of the phase comparator. A base of a PNP transistor Tr1 is connected to the input terminal 23a via a resistor R1. A resistor R2 is connected between the base of the PNP transistor Tr1 and a power supply voltage Vcc. An emitter of the PNP transistor Tr1 is connected to the power supply voltage Vcc, and a collector of the PNP transistor Tr1 is connected to an output terminal 24 of a charge pump circuit.

Further, a base and a collector of a NPN transistor Tr2 are connected to the input terminal 23b via a resistor R3 and an emitter thereof is connected to a ground. A base of a NPN transistor Tr3 is connected to the base of the NPN transistor Tr2. A collector of the NPN transistor Tr3 is connected to the output terminal 24 of the charge pump circuit. In this manner, a current mirror circuit comprising two NPN transistors Tr2 and Tr3 is constructed.

Further, a loop filter (not shown) is connected to the output terminal 24, and a voltage-controlled oscillator (not shown) is connected to the loop filter.

As such, by constituting a current-charging-side circuit with a current mirror circuit, the change in an output current when a power supply voltage is varied, is the same as that of the current caused by the change in a voltage applied to the resistor R3. The amount of change in an input side current when a signal input from the phase comparator is varied, is substantially the same as that of the current caused by the change in the voltage applied to the resistor R3. However, by using the current mirror circuit capable of making the input current substantially equal to the output current, it is possible to regard the change in the input current as the change in the output current as it is. Therefore, the change in the input current is reflected in the output current directly without amplification so that only the amount of change in the voltage applied to the resistor R3 is reflected in the output current (for example, see Japanese Unexamined Patent Application Publication No. 09-331250 (FIG. 2(a)).

However, in the above-mentioned conventional charge pump, since the PNP and NPN transistors respectively generate discharging and charging currents, the PNP transistor regulates the switching speed of the charge pump. As a result, the charge pump cannot be made to respond a higher frequency. Further, although the current mirror circuit is used, the current difference still remains between the charging current and the discharging current. As a result, a noise component is transmitted to the voltage-controlled oscillator via the loop filter, which may deteriorate C/N (carrier to noise ratio) of an oscillation signal.

### SUMMARY OF THE INVENTION

Accordingly, the present invention has been made to solve the above-mentioned problems, and it is an object of the present invention to provide a charge pump capable of responding to a high frequency. Further, it is another object to provide a charge pump capable of drastically reducing the difference between a charging current and a discharging current.

In order to achieve the above-mentioned object, a first aspect of the present invention provides a charge pump which comprises a first constant current source connected between a power supply and an output terminal; and a first NPN transistor and a second NPN transistor inserted between the output terminal and a ground with their collectors connected to the output terminal. A first signal output from a phase comparator is input to a base of the first NPN transistor, and a second signal output from the phase comparator is input to a base of the second NPN transistor.

Further, in a second aspect of the present invention, the charge pump further comprises a third NPN transistor that forms a couple with the first NPN transistor and to a base of which a signal obtained by inverting the polarity of the first signal is input; and a fourth NPN transistor that forms a couple with the second NPN transistor and to a base of which a signal obtained by inverting the polarity of the second signal is input. Collectors of the third NPN transistor and the fourth NPN transistor are pulled up to the power supply, respectively. Emitters of the first NPN transistor and the third NPN transistor are connected to a ground via a second constant current source. Emitters of the second NPN transistor and the fourth NPN transistor are connected to a ground via a third constant current source. Current values of the second and third constant current sources are equal to a current value of the first constant current source.

Further, in a third aspect of the present invention, a current is charged into the first or second NPN transistor from the output terminal when the first signal is at a high level or the second signal is at a low level, and a current is discharged to the output terminal from the power supply via the first constant current source when the first signal is at a low level or the second signal is at a high level.

Further, in a fourth aspect of the present invention, the charge pump further comprises a fourth constant current source connected to the power supply for flowing a current having a current value equal to that of the first constant current source; a fifth constant current source connected to a ground for flowing a current having a current value equal to those of the second and third constant current sources; a fifth NPN transistor inserted between the fourth and fifth constant current sources with its collector connected to the fourth constant current source; and a comparator circuit having two input terminals, one input terminal of the comparator circuit being connected to the collector of the fifth NPN transistor, a voltage equal to the voltage of the output terminal when the first and second signals are not input to the first and second NPN transistors being applied to the other input terminal of the comparator circuit. A base of the fifth NPN transistor is biased by a voltage having a peak value equal to those of the first and second signals. The current of the first constant current source is corrected so as to be equal to the currents of the second and third constant current sources by an output voltage of the comparator circuit.

Further, in a fifth aspect of the present invention, the charge pump further comprises a sixth constant current source that constitutes a current mirror circuit by forming a couple with the first constant current source and makes a reference current flow to the current mirror circuit. The sixth constant current source and the fourth constant current source constitute a current mirror circuit.

Further, in a sixth aspect of the present invention, the charge pump further comprises a seventh constant current source that constitutes a current mirror circuit by forming a couple with each of the second and third constant current sources and makes a reference current flow to the current mirror circuit, wherein the seventh constant current source and the fifth constant current source constitutes a current mirror circuit.

Further, in a seventh aspect of the present invention, the first, fourth, and sixth constant current sources are composed of a PNP transistor, respectively, and the second, third, fifth, and seventh constant current sources are composed of an NPN transistor, respectively.

Further, in an eighth aspect of the present invention, an output terminal of the comparator circuit is connected to a base of the PNP transistor constituting each of the first, fourth, and sixth constant current sources.

Further, in a ninth aspect of the present invention, the charge pump further comprises an eighth constant current source that constitutes a current mirror circuit by forming a couple with the seventh constant current source. The eighth constant current source is a constant current source of the comparator circuit.

### BRIEF DESCRIPTION OF THE DRAWINGS

FIG. 1 is a circuit diagram showing a structure of a charge pump of the present invention; and

FIG. 2 is a circuit diagram showing a structure of a conventional charge pump.

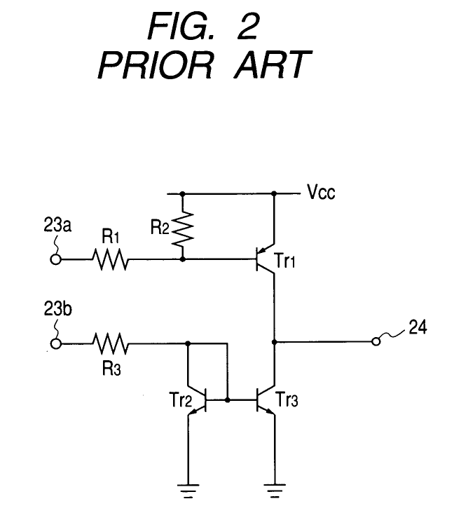

### DESCRIPTION OF THE PREFERRED EMBODIMENTS

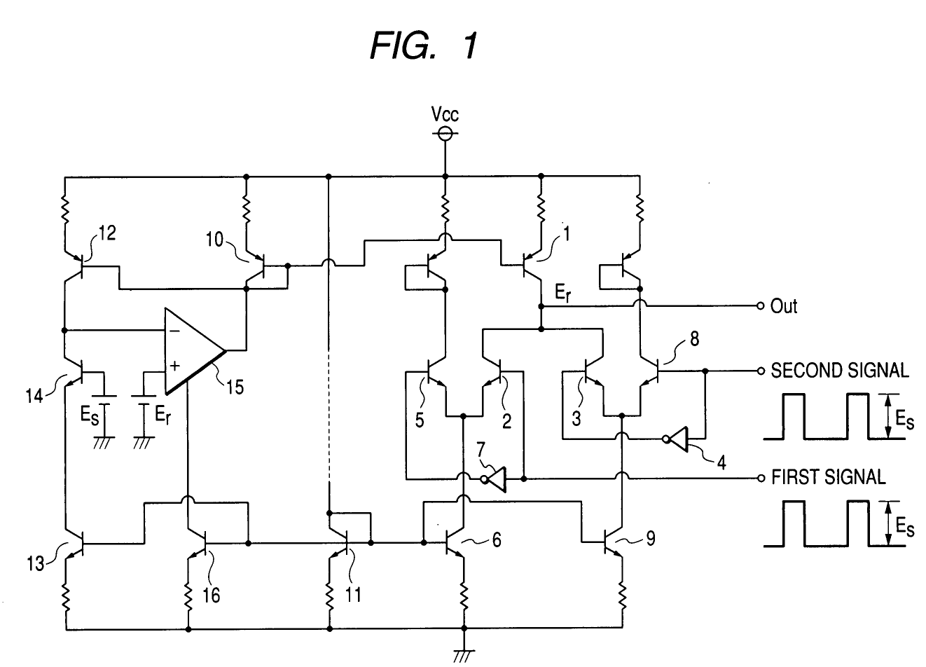

A charge pump of the present invention will be described with reference to FIG. 1. The charge pump is made into an integrated circuit. First, a first constant current source 1 is connected between a power supply Vcc and an output terminal Out. The first constant current source 1 is composed of a PNP transistor. A collector of the PNP transistor 1 is connected to an output terminal Out. The output terminal Out is connected to a loop filter (not shown) which is in turn connected to a voltage-controlled oscillator (not shown).

Further, collectors of a first NPN transistor 2 and a second NPN transistor 3 are connected to the output terminal Out. A first signal that is output from the phase comparator (not shown) for increasing an oscillatory frequency of the voltage-controlled oscillator is input to a base of the first NPN transistor 2. A second signal that is output from the phase comparator for decreasing an oscillatory frequency of the voltage-controlled oscillator is input to a base of the second NPN transistor 3 via an inverter 4.

An emitter of a third NPN transistor 5 forming a couple with the first NPN transistor 2 and an emitter of the first NPN transistor 2 are connected to a ground via a second constant current source 6. A collector of the third NPN transistor 5 is pulled up to the power supply Vcc. In addition, the first signal is input to a base of the third NPN transistor 5 via an inverter 7.

Similarly, an emitter of a fourth NPN transistor 8 forming a couple with the second NPN transistor 3 and an emitter of the second NPN transistor 3 are connected to a ground via a third constant current source 9. A collector of the fourth NPN transistor 8 is pulled up to the power supply Vcc. In addition, the second signal is input to a base of the fourth NPN transistor 8. Therefore, when the first NPN transistor 2 is turned on, the third NPN transistor 5 is turned off, and when the first NPN transistor 2 is turned off, the third NPN transistor 5 is turned on. Further, when the second NPN transistor 3 is turned on, the fourth NPN transistor 8 is turned off, and when the second NPN transistor 3 is turned off, the fourth NPN transistor 8 is turned on. In addition, both the second constant current source 6 and the third constant current source 9 are composed of a NPN transistor.

In a state in which a PLL circuit is locked so that the first signal and the second signal are not input (in a state in which the first signal and the second signal are maintained at a low level), the first NPN transistor 2 is turned off, the second NPN transistor 3 is turned on, and the output terminal Out is maintained at a predetermined voltage (reference voltage). In addition, when the first signal is input, the first NPN transistor 2 is turned on so that a charging current flows into the first NPN transistor 2 from the output terminal Out. Further, when the second signal is input, the second NPN transistor 3 is turned off so that a discharging current flows into the output terminal Out from the power supply Vcc via the first constant current source 1. During this operation, a constant current flows into the second constant current source 6 and the third constant current source 9, respectively. However, the constant currents flowing into the second constant current source 6 and the third constant current source 9 are set such that the constant current values thereof are equal to a value of the current flowing into the first constant current source 1.

The current value of the first constant current source 1 is set by a sixth constant current source 10 that constitutes a current mirror circuit by forming a couple with the first constant current source 1 and makes a reference current flow to the current mirror circuit. The sixth constant current source 10 is composed of a PNP transistor, a base and a collector thereof are connected to each other, and an emitter thereof is connected to the power supply Vcc via a resistor. In addition, the base of the PNP transistor of the first constant current source 1 is connected to the base of the PNP transistor of the sixth constant current source 10. Therefore, a current having a current value equal to the value of the current flowing into the six constant current source 10 flows into the first constant current source 1.

The current values of the second and third constant current sources 6 and 9 are set by a seventh constant current source 11 that constitutes a current mirror circuit by forming a couple with each of the second and third constant current sources 6 and 9 and makes a reference current flow to the current mirror circuit. The seventh constant current source 11 is composed of a NPN transistor, and a base and a collector thereof are connected to each other and are pulled up to the power supply Vcc. An emitter thereof is connected to a ground via a resistor. In addition, the base of the NPN transistor of the second constant current source 6 and the base of the NPN transistor of the third constant current source 9 is connected to the base of the NPN transistor of the seventh constant current source 11. Therefore, a current having a current value equal to the value of the current flowing into the seventh constant current source 11 flows into the second and third constant current sources 6 and 9, respectively.

Further, a fourth constant current source 12 that constitutes a current mirror circuit by forming a couple with the sixth constant current source 10 and a fifth constant current source 13 that constitutes a current mirror circuit by forming a couple with the seventh constant current source 11 are provided. The fourth constant current source 12 is composed of a PNP transistor, an emitter thereof is pulled up to the power supply Vcc via a resistor, and a base thereof is connected to the base of the PNP transistor of the sixth constant current source 10. In addition, the fifth constant current source 13 is composed of a NPN transistor, an emitter thereof is connected to a ground via a resistor, and a base thereof is connected to the base of the NPN transistor of the seventh constant current source 11. In addition, a fifth NPN transistor 14 is inserted between the fourth constant current source 12 and the fifth constant current source 13 so as to detect a current difference between the fourth constant current source 12 and the fifth constant current source 13.

A collector of the fifth NPN transistor 14 is connected to one input terminal (inverting input terminal −) of a comparator circuit 15. In addition, a voltage Es that has a peak level equal to peak levels of the first and second signals is applied to a base of the fifth NPN transistor 14 as a bias voltage. Further, a voltage Er that is equal to the voltage (referred to a reference voltage) of the output terminal Out in a state in which the PLL circuit is locked, that is, in a state in which the first and second signals are not output from a phase comparator so that the first NPN transistor 2 is turned off and the second NPN transistor 3 is turned on is applied to the other input terminal (non-inverting input terminal +) of the comparator circuit 15.

As a result, the fourth constant current source 12, the fifth NPN transistor 14, and the fifth constant current source 13 become replicas of the first constant current source 1, the second NPN transistor 3 (or the first NPN transistor 2), and the third constant current source 9 (or the second constant current source 6). Therefore, a voltage at the collector of the fifth NPN transistor 14 is equal to a reference voltage (the voltage of the output terminal Out).

On the other hand, it is preferable that the current flowing into the first constant current source 1 be equal to the currents flowing into the second constant current source 6 and the third constant current source 9. However, in fact, the respective elements have different characteristics from each other and the collector and emitter currents of the first to fourth NPN transistors 2, 3, 5, and 8 are different from each other. As a result, the value of the current flowing into the first constant current source 1 and the values of the currents flowing into the second constant current source 6 and the third constant current source 9 are different from each other. In this case, even when the PLL circuit is locked, a leak current flows into the output terminal Out so that a signal is output from the phase comparator. Further, a C/N of an oscillation signal is deteriorated caused by a noise component. At this time, the reference voltage of the output terminal Out is varied. Since the change in the reference voltage appears at the collector of the fifth NPN transistor 14 that is a replica, the fifth NPN transistor 14 detects the change in the reference voltage and inputs it to the comparator circuit 15. Then, the comparator circuit 15 compares the changed voltage with the reference voltage Er and performs a feedback of an output voltage corresponding to the difference between the changed voltage and the reference voltage Er to the first constant current source 1, the sixth constant current source 10, and the fourth constant current source 12. Therefore, it is possible to make the current flowing into the first constant current source 1 equal to the currents flowing into the second constant current source 6 and the third constant current source 9.

As a result, since the leak current does not flow into the output terminal Out in a state in which the PLL circuit is locked, the phase noise of the oscillation signal is lowered so that it is possible to prevent C/N of the oscillation signal from deteriorating.

Further, an eighth constant current source 16 that constitutes a current mirror circuit by forming a couple with a seventh constant current source is provided and is used for a constant current source of the comparator circuit 15.

As described above, a charge pump of the present invention comprises a first constant current source connected between a power supply and an output terminal; and a first NPN transistor and a second NPN transistor inserted between the output terminal and a ground with their collectors connected to the output terminal. A first signal output from a phase comparator is input to a base of the first NPN transistor, and a second signal output from the phase comparator is input to a base of the second NPN transistor. Thus, by using only an on/off switching of the two NPN transistors, a current can be discharged to the output terminal from the power supply via the first constant current source and a current can be charged from the output terminal via the first or second NPN transistor. As a result, a switching speed increases as compared to a combination of the PNP transistor and the NPN transistor, which makes it possible to construct a charge pump capable of responding to a high frequency.

Further, the charge pump further comprises a third NPN transistor that forms a couple with the first NPN transistor and to a base of which a signal obtained by inverting the polarity of the first signal is input; and a fourth NPN transistor that forms a couple with the second NPN transistor and to a base of which a signal obtained by inverting the polarity of the second signal is input. Collectors of the third NPN transistor and the fourth NPN transistor are pulled up to the power supply, respectively. Emitters of the first NPN transistor and the third NPN transistor are connected to a ground via a second constant current source. Emitters of the second NPN transistor and the fourth NPN transistor are connected to a ground via a third constant current source. Current values of the second and third constant current sources are equal to a current value of the first constant current source. Thus, the current flowing from the first constant current source necessarily flows into the second constant current source or the third constant current source. As a result, the charging and discharging of the current can be smoothly made.

Further, a current is charged into the first or second NPN transistor from the output terminal when the first signal is at a high level or the second signal is at a low level, and a current is discharged to the output terminal from the power supply via the first constant current source when the first signal is at a low level or the second signal is at a high level. As a result, the charging and discharging of the current can also be made by any one of the first and second signals.

Further, the charge pump further comprises a fourth constant current source connected to the power supply for flowing a current having a current value equal to that of the first constant current source; a fifth constant current source connected to a ground for flowing a current having a current value equal to that of the second and third constant current sources; a fifth NPN transistor inserted between the fourth and fifth constant current sources with its collector connected to the fourth constant current source; and a comparator circuit having two input terminals, one input terminal of the comparator circuit being connected to the collector of the fifth NPN transistor, a voltage equal to the voltage of the output terminal when the first and second signals are not input to the first and second NPN transistors being applied to the other input terminal. A base of the fifth NPN transistor is biased by a voltage having a peak value equal to those of the first and second signals. The current of the first constant current source is corrected so as to be equal to the currents of the second and third constant current sources by an output voltage of the comparator circuit. Thus, a leak current does not flow into the output terminal in a state in which a PLL circuit is locked, so that a noise component caused by the leak current is not generated. As a result, C/N of an oscillation signal does not deteriorate.

Further, the charge pump further comprises a sixth constant current source that constitutes a current mirror circuit by forming a couple with the first constant current source and makes a reference current flow to the current mirror circuit. The sixth constant current source and the fourth constant current source constitute a current mirror circuit. As a result, a current equal to the current flowing into the first constant current source can flow into the fourth constant current source.

Further, the charge pump further comprises a seventh constant current source that constitutes a current mirror circuit by forming a couple with each of the second and third constant current sources and makes a reference current flow to the current mirror circuit. The seventh constant current source and the fifth constant current source constitute a current mirror circuit. As a result, a current equal to the currents flowing into the second and third constant current sources can flow into the fifth constant current source.

Further, the first, fourth, and sixth constant current sources are composed of a PNP transistor, respectively, and the second, third, fifth, and seventh constant current sources are composed of an NPN transistor, respectively. As a result, a stable current flows while a voltage between the respective bases and emitters is kept constant.

Further, an output terminal of the comparator circuit is connected to a base of the PNP transistor constituting each of the first, fourth, and sixth constant current sources. As a result, the current of the first constant current source can be corrected so as to be equal to the currents of the second and third constant current sources.

Further, the charge pump further comprises an eighth constant current source that constitutes a current mirror circuit by forming a couple with the seventh constant current source, and the eighth constant current source is a constant current source of the comparator circuit. As a result, the structure of the comparator circuit can be simplified.

1. A charge pump comprising:
a first constant current source connected between a power supply and an output terminal; and
a first NPN transistor and a second NPN transistor inserted between the output terminal and a ground with collectors of the first and second NPN transistors connected to the output terminal,
wherein a first signal output from a phase comparator is input to a base of the first NPN transistor; and
a second signal output from the phase comparator is input to a base of the second NPN transistor.

2. The charge pump according to claim 1, further comprising:
a third NPN transistor that forms a couple with the first NPN transistor and to a base of which a signal obtained by inverting the polarity of the first signal is input; and
a fourth NPN transistor that forms a couple with the second NPN transistor and to a base of which a signal obtained by inverting the polarity of the second signal is input,
wherein collectors of the third NPN transistor and the fourth NPN transistor are pulled up to the power supply, respectively,
emitters of the first NPN transistor and the third NPN transistor are connected to aground via a second constant current source,
emitters of the second NPN transistor and the fourth NPN transistor are connected to a ground via a third constant current source, and
current values of the second and third constant current sources are equal to a current value of the first constant current source.

3. The charge pump according to claim 1,
wherein a current is charged into the first or second NPN transistor from the output terminal when the first signal is at a high level or the second signal is at a low level, and
a current is discharged to the output terminal from the power supply via the first constant current source when the first signal is at a low level or the second signal is at a high level.

4. The charge pump according to claim 2, further comprising:
a fourth constant current source connected to the power supply for flowing a current having the current value equal to that of the first constant current source;
a fifth constant current source connected to a ground for flowing a current having a current value equal to that of the second and third constant current sources;
a fifth NPN transistor inserted between the fourth and fifth constant current sources with a collector connected to the fourth constant current source; and
a comparator circuit having two input terminals, one input terminal of the comparator circuit being connected to the collector of the fifth NPN transistor, a voltage equal to the voltage of the output terminal when the first and second signals are not input to the first and second NPN transistors being applied to the other input terminal of the comparator circuit,
wherein a base of the fifth NPN transistor is biased by a voltage having a peak value equal to those of the first and second signals, and
the current of the first constant current source is corrected so as to be equal to the currents of the second and third constant current sources by an output voltage of the comparator circuit.

5. The charge pump according to claim 4, further comprising:
a sixth constant current source that constitutes a current mirror circuit by forming a couple with the first constant current source and makes a reference current flow to the current mirror circuit,
wherein the sixth constant current source and the fourth constant current source constitutes a current mirror circuit.

6. The charge pump according to claim 4, further comprising:
a seventh constant current source that constitutes a current mirror circuit by forming a couple with each of the second and third constant current sources and makes a reference current flow to the current mirror circuit,
wherein the seventh constant current source and the fifth constant current source constitutes a current mirror circuit.

7. The charge pump according to claim 5,
wherein the first, fourth, and sixth constant current sources are composed of a PNP transistor, respectively, and
the second, third, fifth, and seventh constant current sources are composed of an NPN transistor, respectively.

8. The charge pump according to claim 7,
wherein an output terminal of the comparator circuit is connected to a base of the PNP transistor constituting each of the first, fourth, and sixth constant current sources.

9. The charge pump according to claim 8, further comprising:
an eighth constant current source that constitutes a current mirror circuit by forming a couple with the seventh constant current source,
wherein the eighth constant current source is a constant current source of the comparator circuit.

10. The charge pump according to claim 4, further comprising:
a seventh constant current source that constitutes a current mirror circuit by forming a couple with each of the second and third constant current sources and makes a reference current flow to the current mirror circuit,
wherein the seventh constant current source and the fifth constant current source constitutes a current mirror circuit.
